(19) United States
(12) Patent Application Publication
(10) Pub. No.: US 2026/0024716 A1
(43) Pub. Date: Jan. 22, 2026

(54) APPARATUS FOR APPLYING ACCELERATED ELECTRONS TO BULK MATERIAL

(71) Applicant: Fraunhofer-Gesellschaft zur Förderung der angewandten Forschung e.V., Munich (DE)

(72) Inventors: Björn MEYER, Dresden (DE); Henrik FLASKE, Dresden (DE); Ralf BLÜTHNER, Dresden (DE); Gösta MATTAUSCH, Dresden (DE); Jörg KUBUSCH, Dresden (DE); Tobias TEICHMANN, Dresden (DE); Michiel Top, Dresden (DE); Elizabeth VON HAUFF, Dresden (DE); Markus HERZOG, Dresden (DE); Fred SCHADE, Dresden (DE); Burkhard ZIMMERMANN, Dresden (DE); Falk WINCKLER, Dresden (DE); Stefan WEISS, Dresden (DE); Thomas WEICHT, Dresden (DE)

(73) Assignee: Fraunhofer-Gesellschaft zur Förderung der angewandten Forschung e.V., Munich (DE)

(21) Appl. No.: 19/339,151

(22) Filed: Sep. 24, 2025

Related U.S. Application Data
(63) Continuation of application No. PCT/EP2024/050609, filed on Jan. 11, 2024.

(30) Foreign Application Priority Data
Apr. 18, 2023 (DE) 10 2023 109 753.9

(51) Int. Cl. H01J 37/147; H01J 37/16

(52) U.S. Cl. CPC H01J 37/1472; H01J 37/16; H01J 2237/006; H01J 2237/0203

(57) ABSTRACT

A device is provided for applying accelerated electrons to a medium, preferably bulk material, comprising a cylindrical electron exit window as a component of a cylindrical housing which surrounds an evacuable space; at least one wire-type, strand-type, rod-type, annular or cylindrical cathode which is arranged within the evacuable space and surrounded by the cylindrical electron exit window, wherein a first power supply unit is electrically conductively connected between the rod-type, annular or cylindrical cathode and the cylindrical electron exit window, so that electrons can be emitted from the wire-type, strand-type, rod-type, annular or cylindrical cathode and accelerated radially away from the cylinder axis of the cylindrical electron exit window in the direction of the cylindrical electron exit window. Also included is a cylindrical protective grid which surrounds the cylindrical electron exit window and defines a first annular free space between the cylindrical electron exit window and the cylindrical protective grid.

### CROSS-REFERENCE TO RELATED APPLICATIONS

This application is a continuation of international patent application PCT/EP2024/050609 filed Jan. 11, 2024, which claims priority under 35 USC § 119 to German patent application 10 2023 109 753.9 filed Apr. 18, 2023. The entire contents of each of the above-identified applications are hereby incorporated by reference.

### TECHNICAL FIELD

The invention relates to an apparatus for generating accelerated electrons and for exposing bulk material to the accelerated electrons.

### BRIEF DESCRIPTION OF THE DRAWINGS

The embodiments may be better understood with reference to the following drawings and description. The components in the figures are not necessarily to scale.

FIG. 1 is a schematic representation of a horizontal segment of an apparatus according to the invention;

FIG. 2 a schematic representation of a vertical segment of the apparatus according to the invention shown in FIG. 1;

FIG. 3 is a schematic representation of a vertical segment of a first alternative apparatus according to the invention;

FIG. 4 is a schematic representation of a vertical segment of a second alternative apparatus according to the invention including a vessel for receiving bulk material particles;

FIG. 5 is a schematic representation of a top view of the vessel for receiving bulk material particles from FIG. 4; and

FIG. 6 is a schematic representation of a vertical section of a third alternative apparatus according to the invention.

### DETAILED DESCRIPTION

Electron beam technology has been used on an industrial scale for several decades for chemical modification, as well as disinfection and sterilization of a wide variety of materials and products. This treatment can be carried out economically at atmospheric pressure if the electrons are first released in a vacuum, then accelerated and finally coupled out into the treatment area through a beam exit window, usually a thin metal foil. In order to penetrate adequately robust electron exit windows suitable for large-scale use and to ensure sufficient treatment depth in the product, acceleration voltages of >80 kV are typically required.

Various methods and beam sources for surface treatment of flat products such as plates and strips, are well established, while treatment of shaped bodies, bulk materials and fluids on all sides still poses problems. Thus, uniformly impinging curved surfaces on all sides with electrons is geometrically problematic due to obscuration effects, variable absorption of electron energy along the gas path, and dose inhomogeneities due to different projection ratios.

With the existing source systems, such as, for example, axial emitters with a fast deflection unit or ribbon emitters (DE 196 38 925 C2) with an elongated cathode, both of which are usually operated with a heated thermionic cathode, product treatment on all sides is only possible in a cumbersome manner, using additional equipment or at a high cost in terms of equipment and/or technology and/or time.

For example, DE 10 2006 012 666 A1 describes a solution which includes axial emitters with associated deflection control and three associated electron exit windows. The three electron exit windows are arranged in such a way that they completely enclose a triangular free space. If a substrate is guided through this free space, it can be exposed to accelerated electrons across its entire cross-section in one treatment pass. However, if the substrate does not have the same triangular cross section as the free space enclosed by the three electron exit windows, the dose distribution of the accelerated electrons on the surface of the substrate will be inhomogeneous. The outlay for the equipment required for this design is also very high, which makes this solution very expensive.

An apparatus is known from DE 4434 767 C1 in which a bulk material flow passes between two surface beam generators and can be exposed to accelerated electrons from both sides. EP 0513 135 B1 describes such two-sided treatment of the free-falling bulk material flow using two mirror-inverted axial beam sources with a scanner. What both solutions have in common is the need to use two electron beam sources along with all of their supply and control components, which still involves a high level of outlay for equipment.

DE 199 42 142 A1 discloses an apparatus in which bulk material is guided past a surface beam generator in multiple free-fall cycles and exposed to accelerated electrons. Due to the plurality of passes, combined with the interim mixing of the bulk material, the probability that the particles of the bulk material are exposed to accelerated electrons on all sides is very high in this embodiment. However, the plurality of passes requires a lot of time to carry out the treatment process.

An annular device for generating accelerated electrons is disclosed in DE 10 2013 111 650 B3, in which all essential components, such as, for example, cathode, anode and electron exit window, are annular, so that by means of such an apparatus an annular electron beam can be formed in which the accelerated electrons move towards the interior of the ring. By means of such an apparatus, for example, strand-shaped substrates which are moved through the ring opening of the apparatus, can be exposed to accelerated electrons from the outside over the entire cross-section of the substrate (DE 10 2017 104 509 A1). The treatment of gaseous media (DE 10 2019 134 558 B3) and bulk materials (DE 10 2013 113 688 B3) having only one such annular source has already been described. The disadvantage here is that such apparatuses are large in volume in terms of in their design due to the external cathodes, insulators and vacuum containers and electron treatment of substrates can only be carried out in the relatively small volume of the interior of the ring.

DE 10 2018 111 782 A1 also describes apparatuses with which a ring of accelerated electrons can be generated, but in this case the movement of the electrons is oriented radially outwards. A more favorable ratio between the size of the electron source and the volume of the treatment area is achieved with this arrangement, which is inverted with respect to the direction of electron propagation compared to DE 10 2013 111 650 B3.

This is all the more so since the cold cathodes described in DE 10 2018 111 782 A1 emit electrons only as a result of stimulation using high-energy ions, which must be provided with an integrated plasma source, which always requires increased effort and increased installation space, especially at the very low pressures needed for a plasma source to maintain the insulating capacity of the vacuum against gas breakthroughs at the technologically required acceleration voltage.

Moreover, this annular source also suffers from the same weakness that all treatment arrangements equipped with only one electron source do, namely the tendency for the energy dose to be deposited unevenly on the various surface areas of the material to be treated (facing toward or facing away from the electron exit window). This is then to be ameliorated by (time-consuming) multiple passes or the provision of electron reflectors on the rear side of the material to be treated facing away from the electron exit window, as described above (the dose contribution of which is, however, several times lower than that applied by the primary beam electrons on the front side). Both methods can only alleviate the problem of insufficient dose homogeneity, and solve it satisfactorily.

An effective method for equalizing the surface dose is to add a rotational movement of the bulk material particles, as described in prior art, such as, for example, in DE 10 2012 209 434 A1. However, this can only be effective if the period of time the bulk material particles are exposed to the electrons is sufficiently long (adjusted for the rotation period for the bulk material particles). This, in turn, means that in the usual treatment, and thus the only economical treatment, of bulk material in free fall, the vertical extent of the electron exit window must be sufficiently large and its opening area must not be interrupted in this (fall) direction.

Treatment technologies with high dose requirements, such as sterilization tasks, pollutant degradation and cross-linking of polymers, impose an additional requirement for vertical extension of the opening area of an electron exit window. This results from the fact that the electrons accelerated inside the beam source transfer part of their energy to the metal foil and the support grid as they pass through the electron exit window causing them to heat up. Electron exit windows are therefore generally cooled, but to avoid thermal damage thereto, the current density of the electrons still needs to be limited. Likewise, when the acceleration voltage is defined by the technology, this corresponds to a limited surface dose rate of the electron beam source. An increase in the dose transferred to the material to be treated is therefore only possible using a longer exposure time to the electrons, i.e., an extension of the opening area of the electron exit window in the direction of fall of the bulk material particles.

Both requirements cannot be met with the apparatus described in DE 10 2018 111 782 A1, in that they conflict with the horizontal arrangement of cooling channels above and below the opening area of the electron exit window, which is implicitly assumed in the cross-sectional drawings. It is known that the distance between these cold surfaces to which the absorbed portion of the electron energy must be dissipated by heat conduction through the support grid must not be chosen too large (being limited to only about 7 to 10 cm in practically designed setups), since the temperature increase of metal foil and support grid increases linearly with the heat flux density and quadratically with respect to the distance to the heat sink (i.e., the actively cooled edge of the opening area). The resulting limitation of the vertical extent of the uninterrupted opening area not only limits the uniformity that can be achieved, but also the dose that can be achieved on the material to be treated in a single pass.

Particularly in bulk material handling, the protection of the metal foils from the bulk material particles themselves, but also from frequently encountered foreign bodies, abrasion and dust, is of great importance. Larger particles can cause direct mechanical damage to the foil; the accumulation of dust would impair the transmission of electrons (and thus reduce the dose transferred to the product) and increase the locally absorbed portion of the electron energy (thus causing localized thermal damage to the metal foil and thus promoting vacuum leaks). It is therefore obvious that process-related components are critical for protecting the electron exit window, however, DE 10 2018 111 782 A1 does not contain any technical teaching in this regard.

US 2008/0267354 A1 also describes annular apparatuses with which a high dose of X-rays and also electron beams can be generated. Due to the generation of a high dose of X-rays, such apparatuses are unsuitable for electron treatment of sensitive products, such as seeds, or products entering the food chain for humans or livestock.

The invention is therefore based on the technical problem of creating an apparatus for generating accelerated electrons whereby the disadvantages of the prior art can be overcome. In particular, an apparatus with a compact design is to be created with which, for example, bulk material, but also hollow bodies, can be uniformly subjected from the inside to accelerated electrons on all sides in only one pass, thereby achieving high dose values in the product and a long continuous operating time.

An apparatus according to the invention for exposing bulk material to accelerated electrons includes a cylindrical electron exit window as a component of a cylindrical housing which encloses an evacuable space; at least one wire-shaped, strand-shaped, rod-shaped, annular or cylindrical cathode which is arranged within the evacuable space and enclosed by the cylindrical electron exit window, where electrons can be emitted from the wire-shaped, strand-shaped, rod-shaped, annular or cylindrical cathode and accelerated radially away from the cylinder axis of the cylindrical electron exit window towards the cylindrical electron exit window. In a preferred embodiment, the wire-shaped, strand-shaped, rod-shaped, cylindrical or annular cathode is designed as a thermal emitter or as a hot cathode. Such electron sources require significantly less space than plasma-stimulated cold cathodes. Their heating to emission temperature can be achieved directly using current passing through the cathode itself or indirectly (by means of thermal radiation or electron impact) using a heating conductor placed inside the cathode and there separated from the electrical potential of the latter.

An apparatus according to the invention further includes a cylindrical protective grid which encloses the cylindrical electron exit window and defines a first annular free space between the cylindrical electron exit window and the cylindrical protective grid; an electron reflector which in turn encloses the cylindrical protective grid and thus defines a second annular free space between the cylindrical protective grid and the electron reflector; and a number of gas pipes which extend within the first annular free space parallel to the cylinder axis of the cylindrical electron exit window. All gas pipes are spaced by an identical first measure from the cylinder axis of the cylindrical electron exit window and by an identical second dimension from an adjacent gas pipe. The gas pipes can be designed, for example, with a round cross-section or, preferably, a rectangular cross-section. Furthermore, each gas pipe has, on two opposite wall regions, at least one opening through which a first gas can be introduced into the first annular free space. In one embodiment, a number of bores are formed on the two opposing wall regions and are arranged along the longitudinal extent of the gas pipes. The bores in the gas pipe walls extend at least over a gas pipe length region opposing the electron exit window. In another embodiment, a slot is formed in the wall of the gas pipes at each of the opposing wall regions and extends along the longitudinal extent of the gas pipes at least across the height of the electron exit window.

In an apparatus according to the invention, the bulk material to be exposed to accelerated electrons is passed through the second annular free space between the electron reflector and the cylindrical protective grid. The bulk material is then also exposed to accelerated electrons within this second annular free space, hence the second annular free space is also referred to as the treatment area. Electrons are initially emitted from the centrally arranged rod-shaped, annular or cylindrical cathode. The cathode can be designed, for example, as a hot cathode or as a discharge-stimulated cold cathode. In a preferred embodiment, an electric current flows through the rod-shaped, annular or cylindrical cathode, which is heated thereby, and thus constitutes a thermal emitter or hot cathode. For this purpose, the rod-shaped, annular or cylindrical cathode is electrically conductively connected to the negative pole of a first power supply device. The positive terminal of the first power supply is electrically connected to the cylindrical electron exit window, so that the cylindrical electron exit window has an electrical anode potential. In one embodiment, the electron exit window has the electrical ground potential. Due to the anode potential applied to the cylindrical electron exit window, the electrons emitted by the rod-shaped, annular or cylindrical cathode are accelerated radially outwards towards the cylindrical electron exit window. After exiting the cylindrical electron exit window, the accelerated electrons cross through the first annular free space, pass through the cylindrical protective grid and, in the second annular free space, strike the bulk material to be exposed to the accelerated electrons.

At least the inner side of the electron reflector, which defines the second annular free space towards the outside, consists of an electron-reflecting material, at least in the region opposing the electron exit window. In this way, those electrons that reach the inside of the electron reflector can be reflected by the electron reflector and contribute to exposing the bulk material to accelerated electrons. The aforementioned region of the electron reflector can consist entirely of a material reflecting the electrons, or the electron reflector can be coated, only on the inside in the aforementioned region, with a material reflecting the electrons. One example of a suitable material for reflecting electrons is a temperature-resistant metal with a high atomic number, such as tungsten or a tungsten alloy. It is advantageous if at least the electron-reflecting region of the electron reflector is cooled so that it does not heat the air in the treatment area. Such cooling can be implemented as water cooling, for example.

In a preferred embodiment of the invention, the cylinder axis of the annular electron exit window is oriented vertically so that, for example, bulk material which is to be exposed to accelerated electrons can fall in free fall within the second annular free space between the cylindrical protective grid and the electron reflector. The cylindrical protective grid keeps the falling bulk material away from the electron exit window and thus protects it from mechanical damage caused by the bulk material. Since it is not always possible, especially in a mobile system, to orient a system in such a way that the cylinder axis is completely vertical, the orientation of the cylinder axis of the annular electron exit window can deviate from the vertical by an angle of approximately 10° or less, including when treating bulk material.

The invention is described in more detail with reference to below using an exemplary embodiment.

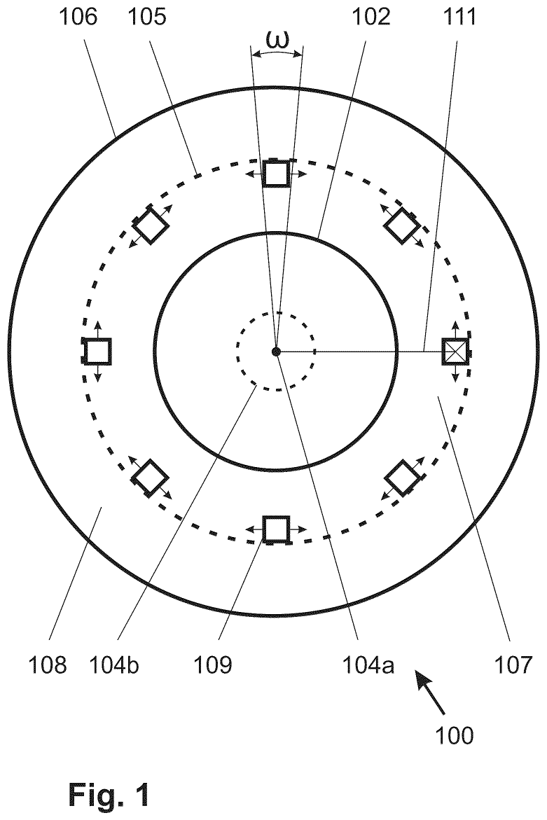

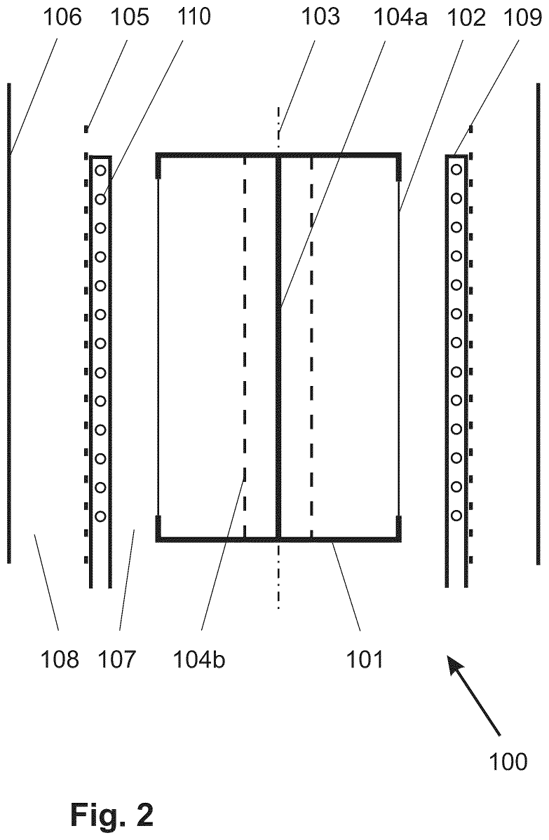

In FIGS. 1 and 2, one and the same apparatus 100 according to the invention is shown schematically, with FIG. 1 showing a horizontal section and FIG. 2 showing a vertical section. The apparatus 110 includes a cylindrical housing 101 which encloses an evacuable space. A vacuum can be maintained within the evacuable space by means of at least one vacuum pump, which is not shown in the figures for reasons of clarity, but is known from the prior art. A wall region of the housing 101 is embodied as a cylindrical electron exit window 102. The cylindrical electron exit window 102 has a circular cross-section and a vertically oriented cylinder axis 103 and encloses a centrally arranged cathode 104a. The cathode 104a is rod-shaped, extends along the cylinder axis 103, and consists of a wire through which an electric current flows. The material of the cathode 104a may comprise, for example, at least one of the chemical elements tungsten or tantalum. The cathode 104a is heated as a result of the flow of current, which in turn leads to the thermal emission of electrons. The cathode 104a is thus embodied as a hot cathode. The electrons emitted by the cathode 104a are accelerated radially outward toward the cylindrical electron exit window 102 because the cylindrical electron exit window 102 has an electrical anode potential. For this purpose, the cylindrical electron exit window 102 is electrically connected to the positive pole of a first power supply unit and the cathode 104 is connected to the negative pole of the first power supply unit. For reasons of clarity, the first power supply unit is not shown in the figures. The apparatus 100 is thus embodied as a cylindrical electron beam generator which generates a ring of accelerated electrons, whose movements are directed radially outward.

However, forming the cathode of an apparatus according to the invention as a thin wire, as is done in cathode 104a, also entails additional requirements. The high operating temperature of the wire required for thermal emission of electrons leads to recrystallization of the wire material and to changes in the length of the wire. If it is made of metal, an increase in temperature generally results in an extension of the wire. However, the extension of a vertically firmly clamped wire leads to its compression and bending, so that it no longer extends exactly along the cylinder axis 103, which can adversely affect the homogeneity of circumferential electron emission and ultimately the dose distribution on the material to be treated. The embrittlement of a metal wire, which is also associated with recrystallization, can even cause breakage as a result of this compression, especially under alternating thermal stress. As an alternative to a metal wire, carbon fibers can therefore also be used as a hot cathode, so that the hot cathode is strand-shaped. However, such carbon fibers contract when the temperature increases. If clamped tightly, high tensile stresses will develop, which would cause the cracking of such a hot cathode.

It is therefore advisable to firmly clamp a wire-shaped, strand-shaped, rod-shaped, annular or cylindrical hot cathode, for example, only on the upper end, while at the bottom it is guided radially, but mounted so that it can move axially. When the apparatus is operated vertically, the upper end corresponds to the end furthest away from the direction of action of earth's gravity vector. It is advantageous to make contact with the hot cathode at the lower end using a clamping piece which, by dint of its weight, always maintains a moderate tensile stress that is sufficient to tighten the cathode wire, but prevents it from flowing or cracking. Alternatively, the hot cathode can be securely clamped or supported only at the lower end and contacted at the upper end with an axially movable clamping piece. When the apparatus is operated vertically, the lower end corresponds to the end closer to the direction of action of the Earth's gravity vector.

If a hot cathode is heated directly by a current flow, an electrical potential gradient is created in the longitudinal direction. This causes a change in the electric field strength and thus in the electron emission in the longitudinal direction of the hot cathode. In order to achieve a more uniform distribution of electron emission along the longitudinal extension of the hot cathode, the potential gradient must be minimized. To bring this about this, a hot cathode can also be heated indirectly (for example by means of thermal conduction, thermal radiation, or electron impact).

For this purpose, in an advantageous embodiment, a rod-, strand- or wire-shaped heating element is arranged inside a cylindrical hot cathode, centered along the cylinder axis of the cylindrical hot cathode and electrically insulated from the cylinder wall, and heated by means of current flow. The heating element must be operated at high temperature in order to heat the hot cathode to emission temperature, and is therefore made of a material with a high melting temperature (greater than 1500 K). Refractory metals (such as tungsten, tantalum, or molybdenum) or carbon fibers are suitable for this purpose.

In a first variant of this embodiment, a high-temperature-resistant, electrically low conductive material (such as boron nitride or zirconium oxide) is introduced between the central heating element and the cylindrical hot cathode, and heat of the central heating element is transferred to the cylindrical hot cathode by thermal conduction.

In a second variant of the above-mentioned embodiment, the heating element and the hot cathode are mounted contactlessly and the heat of the central heating element is transferred to the cylindrical hot cathode by way of thermal radiation. A particularly advantageous embodiment of this variant is achieved if the central heating element and the cylindrical hot cathode are each connected in an electrically conductive manner to one another at one end and the current is returned through the heating element via the cylinder wall of the cylindrical hot cathode. This results in a compensation of the magnetic field associated with the heating current, which adversely affects electron propagation (i.e., its extinction in the external environment of the hot cathode). The cylindrical wall of the hot cathode is made sufficiently thick so that it has a low electrical resistance and thus the potential gradient in the longitudinal direction remains low, as desired. This results in a more homogeneous extraction field around the emission surface of the cylindrical hot cathode and thus in a more uniform electron emission distribution along the longitudinal axis of the hot cathode.

In a third variant of the above-mentioned embodiment, the heating element and the hot cathode are also mounted contactlessly and completely electrically insulated from one another. The hot cathode can then be connected to the positive terminal and the heating clement to the negative terminal of an additional power supply. If the heating element is heated to emission temperature, the electrons emitted by it are drawn to the inner wall of the hot cathode, and heat it through electron impact.

In all three variants described, it is advisable that the cylindrical hot cathode be made of a material with a high melting point (greater than 1500 K) and a moderate to low work function (less than 5 eV). Suitable materials for this purpose include refractory metals (tungsten, tantalum, molybdenum, niobium), titanium, zirconium or stainless steel, all of which can be coated with compounds (such as oxides) in order to reduce the electron work function, as well as ceramics with a high melting temperature (such as rare earth borides, with lanthanum hexaboride being the most well-known representative).

Indirect heating of a cylindrical hot cathode also produces a change in its length. With such a geometry, it is advisable to clamp or support the hot cathode at the lower end and to enable stress-free length compensation by means of axially movable, radially guided upper clamping and contacting.

Furthermore, it is expedient for all embodiments of a hot cathode to provide radial adjustability of the upper and lower clamping and contacting points in order to bring about optimal orientation of the hot cathode along the vertically oriented cylinder axis 103 and thus a uniform field strength and a resulting uniform electron emission along the whole cathode circumference.

In the apparatus 100, the cathode 104a is further enclosed by a cylindrical control grid 104b having a diameter that is smaller than the diameter of the cylindrical electron exit window 102. The grid structure of the cylindrical control grid 104b is fully formed. The cylindrical control grid 104b is made of an electrically conductive material, is electron-transparent, and has an electrical voltage potential that is slightly more positive than the electrical voltage potential of the cathode 104a. In one embodiment, the cylindrical control grid 104b has a differential voltage from the cathode 104a of approximately +20 V to approximately +2000 V. The voltage potential for the cylindrical control grid can be provided by means of a separate second power supply unit or, alternatively, by means of a separately controllable second channel of the first power supply unit. As an electron-transparent gauze cylinder, the cylindrical control grid 104b reduces the electric field strength inside the gauze cylinder, enables the installation of optional holders for the cathode wire along the longitudinal extension, and ensures uniform, electron extraction on all sides, which is tolerant within certain limits even against positional deviations of the cathode wire, regardless of the accelerating voltage acting in the external space. Furthermore, the adjustability of the voltage difference between the control grid and the cathode offers, in addition to the variation of the heating current flowing through the cathode wire, a second, very dynamic option for controlling the emitted electron current. A similar cylindrical control grid in combination with a cathode wire is already known from prior-art ribbon emitters. In the case of base elements for clamping the cathode wire and the cylindrical control grid 104b in an apparatus according to the invention, it is therefore also possible to resort to constructive solutions which are known from prior-art ribbon emitters, e.g., from DE 196 38 925 C2.

The cylindrical electron exit window 102 may optionally have a support grid known from the prior art which provides the cylindrical electron exit window 102 with the required mechanical stability. Likewise, this support grid may include water cooling, as is known from the prior art. For reasons of clarity, the figures describing the invention also do not show such a support grid.

The apparatus 100 according to the invention further includes a cylindrical protective grid 105, which encloses the cylindrical electron exit window 102, and an electron reflector 106, which in turn encloses the cylindrical protective grid 105. The electron reflector 106 is designed as a hollow cylinder. The cylinder axes of the cylindrical protective grid 105 and the electron reflector 106 are identical to the cylinder axis 103 of the cylindrical electron exit window 102, so that the cylindrical protective grid 105 defines a first annular free space 107 between the cylindrical electron exit window 102 and the cylindrical protective grid 105 and the electron reflector 106 defines a second annular free space 108 between the cylindrical protective grid 105 and the electron reflector 106. The height extensions of the cylindrical protective grid 106 and the electron reflector 106 extend at least over a region opposite the height extension of the cylindrical electron exit window 102. For example, atmospheric conditions may form both within the first annular free space 107 and the second annular free space 108.

As explained above, the cylindrical electron exit window 102 has an electrical

anode potential, so that the electrons emitted by the cathode 104a through which current flows are initially accelerated towards the cylindrical electron exit window 102. Upon exiting the cylindrical electron exit window 102, the accelerated electrons pass through the first annular free space 107, through the cylindrical protective grid 105 and, in the second annular free space, strike the bulk material to be exposed to the accelerated electrons. The bulk material particles move in free fall through the second annular free space 108, also known as the treatment area. At least in the region of the electron reflector 106 which opposes the cylindrical electron exit window 102, the electron reflector 106 consists, at least on the inside, of a material which reflects the electrons, so that the accelerated electrons which reach the electron reflector 106 can be reflected and fed back to the bulk material particles which are to be exposed to electrons.

Due to the energy input into the electron reflector 106 as a result of the accelerated electrons striking the electron reflector 106, the electron reflector 106 includes water-flow channels (not shown in the figures for reasons of clarity), by means of which the thermal energy introduced into the electron reflector is dissipated. This simultaneously also slightly cools the air in the treatment area. Such cooling channels can, for example, be attached to the outside of the electron reflector 106.

The cylindrical protective grid 105, delimiting the first annular space 107 to the outside, keeps the bulk material guided through the treatment area away from the cylindrical electron exit window 102 and thus reduces the risk of the bulk material to be treated with electrons causing mechanical damage to the cylindrical electron exit window 102. The first annular free space 107 is therefore also referred to below as the protection area. The cylindrical protective grid 105 extends along the cylinder axis 103 at least over a region which opposes the cylindrical electron window and preferably consists of an electrically conductive and heat-resistant material, such as, for example, molybdenum or stainless steel. In one embodiment, the cylindrical protective grid 105 is designed such that it has transparency of at least 75% with respect to the accelerated electrons. This ensures that a sufficient number of electrons reach the bulk material to be exposed to electrons in the treatment area.

Although the cylindrical protective grid 105 ensures that larger particles of the bulk material to be exposed to electrons are kept away from the electron exit window 102, bulk materials usually also include dust particles that may pass through the protective grid 105 and settle on the electron exit window 102, causing it to absorb significantly more electron energy in the contaminated regions and be thermally overloaded and destroyed.

This risk of damage would become increasingly more noticeable the longer the cylindrical electron source and all the components described above are formed, however, this is the key to achieving higher dose rates.

According to the invention, the apparatus 100 therefore also includes a number of gas pipes 109 which extend within the first annular free space 107 parallel to the cylinder axis 103 of the cylindrical electron exit window 102. With their previously described orientation, the gas pipes 109 represent, as a module, the component which makes possible free scalability of the axial length (vertical extension) of the cylindrical electron source and the function-determining components thereof, which is desirable for higher dose rates. In a preferred embodiment, all gas pipes 109 are spaced apart by an identical first dimension from the cylinder axis 103 of the cylindrical electron exit window 102 and by an identical second dimension from a respective adjacent gas pipe 109. In the embodiment described in the example, the gas pipes 109 have a rectangular cross section. Alternatively, however, other geometric shapes for the cross section of the gas pipes 109, such as a circular cross section, may also be realized. Each gas pipe 109 has bores 110 on two opposing wall regions along the longitudinal extent of the gas pipes 109, through which a first gas can be introduced into the first annular free space 107. The bores, which are formed in the gas pipes 109 with a preferred diameter of approximately 1 mm or smaller, extend at least over a gas pipe length region which opposes the cylindrical electron exit window 102 and therefore matches the height of the cylindrical electron exit window 102. The bores 110 are preferably introduced in in the gas pipes 109 and the gas pipes 109 are oriented such that the exit direction of the first gas through a bore 110 runs within a horizontal plane of the apparatus 100 and is oriented perpendicular to a straight line 111 which is drawn from the cylinder axis 103 of the cylindrical electron exit window 102 to the center of a horizontal interface of an associated tube 109. Arrows in FIG. 1 illustrate the exit direction of the first gas through the bores 110. For example, air or an inert gas can be used as the first gas. For the sake of completeness, it should be mentioned that the gas pipes 109 are connected by means of a piping system to a reservoir within which the first gas is located. The reservoir can also include the ambient air of an apparatus according to the invention.

Instead of the individual bores 110, a vertical slot can alternatively be inserted in the walls of the gas pipes 109 on the opposing wall regions of the gas pipes 109, and which extends over the height of the electron exit window 102. The vertical slot has a width of approximately 1 mm or less.

The first gas introduced into the protection area through the bores 110 escapes to the outside through the cylindrical protective grid 105 and is discharged in the treatment area with the flow of the bulk material to be exposed to accelerated electrons. The first gas flowing through bores 110 fulfills two tasks. Firstly, the first gas penetrating outwards through the cylindrical protective grid 105 prevents dust particles from passing into the interior through the cylindrical protective grid 105 towards the electron exit window 102, thus protecting the electron exit window 102 from a parasitic coating of dust particles. The first gas is therefore also referred to as the protective gas. Secondly, the flow of the protective gas within the first annular free space 107 simultaneously cools the cylindrical electron exit window 102. As a result, water cooling of a support grid for the electron exit window 102 may also be dimensioned smaller.

It is advantageous if the gas pipes 109 are in mechanical contact with the cylindrical protective grid 105 or if the gas pipes 109 are mechanically connected to the cylindrical protective grid 105. This mechanically stabilizes the cylindrical protective grid 105 and holds it in position. The gas pipes 109 and the cylindrical protective grid are then designed, for example, as a compact assembly which can be integrally removed during maintenance.

In a further embodiment, the diameter of the cylindrical protective grid 105 is selected such that its cylindrical wall is arranged centrally between the electron reflector 106 and the cylindrical electron exit window 102.

In another embodiment, the annular width of the first annular free space 107 is selected such that the gas pipes 109 take up fill at least 90% of the distance between the cylindrical electron exit window 102 and the cylindrical protective grid 105.

However, one disadvantage of using the gas pipes 109 in an apparatus according to the invention is that the gas pipes 109 are not sufficiently transparent for accelerated electrons. Therefore, each of the gas pipes 109 ensures that in an angular range with an angle ω, a sufficient number of accelerated electrons, originating from the cathode 104a, cannot reach the second annular free space directly, or in other words, each of the gas pipes 109 ensures that the treatment area is shadowed in the angular region with the angle ω with respect to the accelerated electrons. These angular regions with the angle ω are therefore also referred to below as shadowing angle regions. Within the shadowing angle regions, it is impossible to subject bulk material particles to a required dose of accelerated electrons. Therefore, a bulk material to be exposed to accelerated electrons should be prevented from entering the shadowing angle ranges of the treatment area. At the top of the second annular free space 108, at which the bulk material to be exposed to accelerated electrons is introduced into the treatment area, it is therefore possible, for example by means of mechanical diaphragms, to prevent the bulk material particles to be exposed to accelerated electrons from entering the shadowing angle regions. In order to ensure economical operation of an apparatus according to the invention, the number of gas pipes 109 and their cross-sectional dimensions should be selected such that the sum of all shadowing angle ranges of the second annular free space 108 does not cover more than 20% of the cross-sectional area of the second annular free space 108.

Since these shadowing angle regions are unfortunately not preventable in an apparatus according to the invention, but are inevitable, it is advantageous if other
components of an apparatus according to the invention which also cause shadowing of the treatment area or which must not be exposed to the accelerated electrons are arranged directly within the shadowing angle ranges. For example, it is advantageous if vertically extending electrical lines, for example for sensor elements or measuring devices, vertically extending cooling water lines for the support grid of the cylindrical electron exit window 102 or fastening elements for components of the apparatus according to the invention are arranged within the shadowing angle regions.

Starting from the shadowing angle regions, for example, rod-shaped or strip-shaped sensor elements can project like antennas into the angular regions traversed by accelerated electrons and can be used to determine the circumferential and/or vertical distribution of the electron current density. The actual values recorded by the sensor elements are fed to an evaluation device and compared with a target value within the evaluation device. The electrical parameters of the apparatus can then be controlled depending on the result of the comparison.

Alternatively or additionally, sensors, for example in the form of metal sheets electrically insulated from ground, can also be attached to the inner wall of the electron reflector 106, and can detect parameter values of the electrons striking there and forward these values to the evaluation device in order to make statements about the circumferential and/or vertical distribution of the electron current density and to initiate control processes dependent thereon.

For reasons of energy efficiency and reducing the thermal load of the electron source, it is advantageous not to allow electrons to strike the electron exit window or its vertical supporting and cooling structures within the shadowing angle regions, as these would be absorbed and thus contribute to the parasitic heating of the electron beam generator, but not to its technological dose rate. For this purpose, the cylindrical control grid 104b and/or the electron exit window 102 can be designed such that they are not fully transparent to electrons, but instead are provided with defined opening regions that are aligned with the angular regions of the electron exit window 102 which are not covered by shadowing angle regions with the angle ω. Electrons that were emitted by the hot cathode and strike the control grid 104b in the closed shadowing angle region are absorbed there and do not reach the electron exit window 102. Since they only pass through a small potential difference and thus have absorbed little energy, this beam-forming absorption at the control grid does not constitute a serious loss factor.

In a further embodiment of the invention, the electron reflector 106 is electrically insulated from the electrical ground potential. An electrical voltage potential which is suitable for igniting and maintaining an atmospheric pressure plasma within the second annular free space 108 can be generated at the electron reflector 106 by means of a third power supply device. It is particularly advantageous to select the voltage difference such that a non-independent glow discharge supported by the beam electrons forms in the second annular free space 108. This is distinguished in that it is stabilized as a large-area, uniform volume discharge, i.e., its transformation to a filament or arc discharge can be prevented. This requires a voltage of 1 kV to 5 kV per 1 cm radial distance between the electron reflector 106 and the protective grid 105. A particularly high power density of this atmospheric pressure plasma is achieved when the energy supply is pulsed by the third power supply device. It is known that plasmas do not have a deep-acting effect, but rather at least near-surface chemical and disinfecting effects on media impinged with the plasma. A plasma inherently acts on an object, such as a bulk material particle, on all sides. In an apparatus according to the invention, if the bulk material to be exposed to accelerated electrons is in the form of seeds, for example, in which microorganisms adhering to the seeds are to be rendered harmless by means of the accelerated electrons, the formation of such a plasma within the second annular free space is particularly advantageous. The near-surface action of the plasma on all sides of the seeds helps to inactivate the microorganisms adhering to the seeds and to disinfect the seeds.

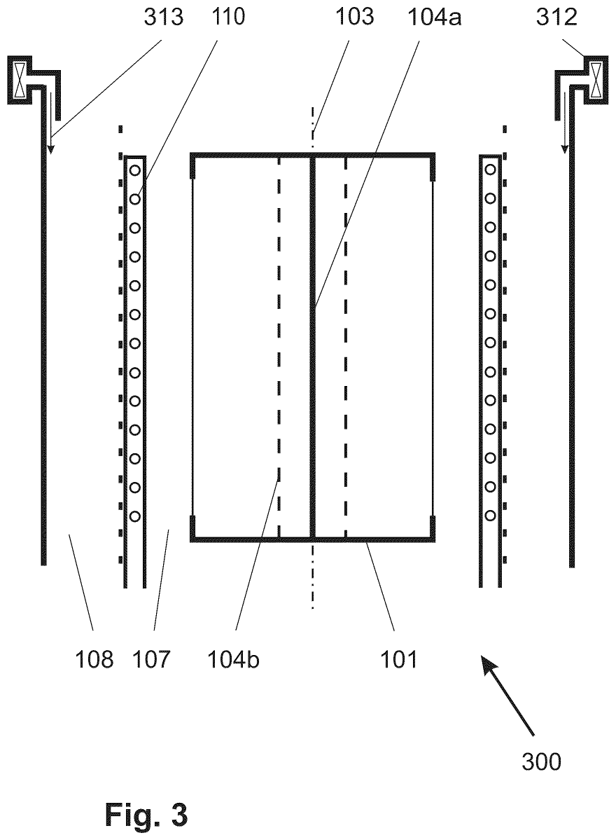

It has already been explained that an apparatus according to the invention can have a cooling device by means of which the electron reflector 106 of an apparatus according to the invention, and thus also the second annular free space 108, can be cooled. In particular, when bulk materials within the second annular free space 108 are to be exposed to accelerated electrons, a cooling device for the electron reflector 106 alone is insufficient in order to prevent heating of the second annular free space 108. If the bulk material is in the form of seeds, for example, heating of the second annular free space 108 can lead to thermal damage of the seeds. In FIG. 3, an alternative apparatus 300 according to the invention is shown schematically as a vertical section. The apparatus 300 initially comprises all components and their functionalities as described for the device 100 in FIGS. 1 and 2. In addition, the device 300 includes at least one device 312 for forming a flow 313 of a second gas within the second free space 108. The device 312 can be designed, for example, as a blower or fan. The flow 313 of the second gas is oriented such that it is identical to the direction of movement of the bulk material, which is guided through the second annular free space 108 and there is exposed to accelerated electrons. The flow 313 of the second gas essentially accomplishes two tasks. Firstly, blockages within the second annular free space 108 are avoided if the medium to be exposed to accelerated electrons is designed as a bulk material, in that the second annular free space 108 is virtually permanently purged by the flow 313 of the second gas. The second gas is therefore also referred to as purge gas. Secondly, a constant gas exchange within the second annular free space 108 prevents the second annular free space 108 from heating up. For example, air or an inert gas can be used as a second gas.

In apparatus 300, the device 312 for generating the flow 313 of a second gas is arranged at the inlet region of the second annular free space 108 and is designed as a blower or a fan. Alternatively or additionally, however, such a device can also be arranged at the outlet of the second annular free space 108 and designed there, for example, as a suction pump, such that by means of the suction pump a suction flow is generated within the second annular free space 108 and by means thereof the air is pulled out of the second annular free space 108.

It is important that the volumetric flow rate of the first gas into the first annular free space 107 can be metered independently of the flow 313 of the second gas within the second annular free space 108. In this way, an aerodynamic balance of the two gas flows can be achieved and it is possible to suppress the transfer of particles, e.g., dust or grain grit, from the second annular free space 108 into the first annular free space 107.

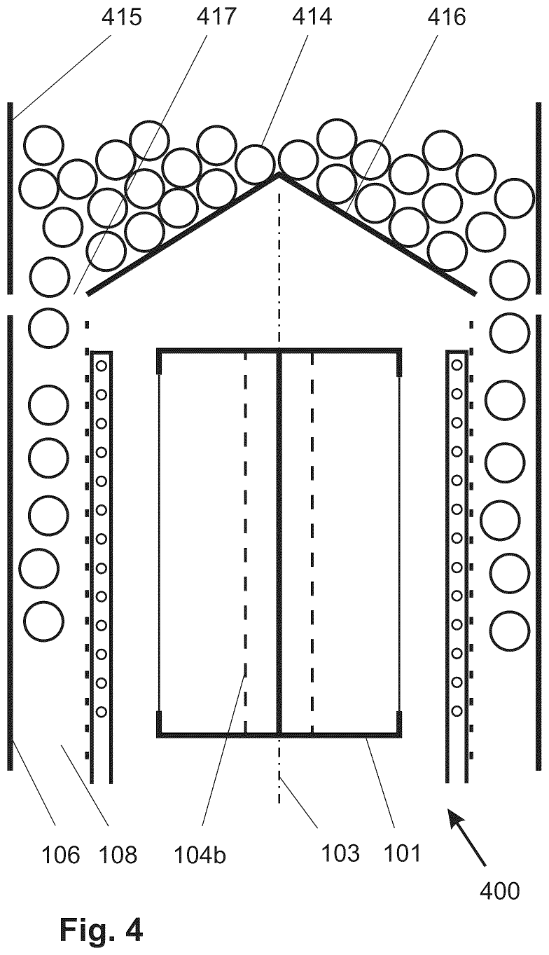

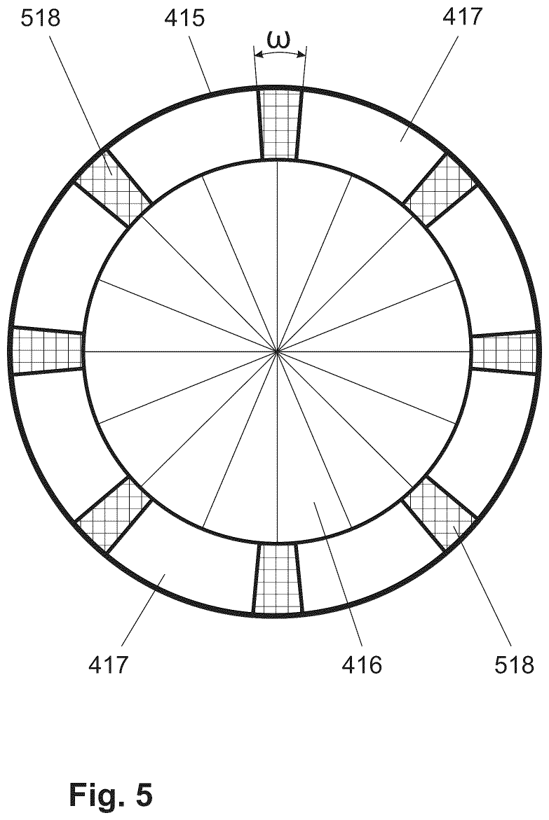

FIG. 4 shows a schematically a vertical section of a second alternative apparatus 400 by means of which bulk material particles 414 are to be exposed to accelerated electrons. Initially the apparatus 400 may include all components and their functionalities as described for the apparatuses 100 and 300 from FIGS. 1, 2 and 3. The cylinder axis 103 of the cylindrical electron exit window of the apparatus 400 is oriented vertically. An apparatus for separating the bulk material particles 414 is additionally arranged above the cylindrical electron beam generator with the cylindrical housing 101. The apparatus for separating the bulk material particles 414 includes a vessel for receiving the bulk material particles 414. The vessel in turn comprises a cylindrical side wall 415 and a conical bottom wall 416, where an annular gap 417 is formed between the cylindrical side wall 415 and the conical bottom wall 416. Alternatively, the bottom wall of the vessel can also be disc-shaped. Due to the slope of the bottom wall, a conical bottom wall has the advantage that the bulk material particles are set into a rolling motion, which then continues as rotational motion in free fall. The vessel is shown schematically in plan view in FIG. 5. The cone tip of the conical bottom wall is directed upwards and positioned exactly on the extended cylinder axis of the cylindrical electron exit window 103. Due to the conical shape of the bottom wall 416, the bulk material particles 414 in the lower region of the cylinder 415 are forced onto an annular outer region in which the bulk material particles 414 fall out through the opening in the form of the annular gap 417. The annular gap 417 is arranged rotationally symmetrically about the elongated cylinder axis 103 of the cylindrical electron exit window and has a gap width such that, with respect to the gap width, only one bulk material particle 414 after the other may fall through the annular gap 417. Relative to the length of the annular gap 417, several bulk material particles 414 can of course fall through the annular gap 417 at the same time.

In one embodiment, the cylindrical wall 415 of the vessel and the electron reflector 106 of the electron beam generator form a continuous unit such that both components are combined to form a single continuous hollow cylinder.

In the angular regions of the annular gap 417, which are identical to the shadowing angle regions of the second annular free space with the angle ω, the annular gap 417 is provided with apertures 518, which prevent bulk material particles 414 from falling through the annular gap 417 in these angular regions. Optionally, the apertures 518 may have vertically downwardly extending side walls that extend downwards through the second annular free space fully ensuring that no bulk material particles 414 can enter the shadowing angle regions.

In this way, a thin, annular curtain of descending bulk material particles is created and is only interrupted in the shadowing angle regions and can then be exposed to accelerated electrons within the second annular free space.

Due to the gravitational acceleration of the falling bulk material particles, their speed increases continuously as they cross through the second annular free space, such that the electron dose acting on the bulk material particles decreases continually during their free fall through the second annular free space. An additional flow of a second gas within the second annular free space, as described for apparatus 300 of FIG. 3, can further increase the speed of the falling bulk material particles and thus further reduce the acting electron dose during the fall of the bulk material particles. In addition, the protective gas also passes through the cylindrical protective grid into the second annular free space, and must be discharged downwards along with the bulk material flow, so that the volume flow of both gases to be discharged downwards whereby, with a constant cross-sectional area of the second annular free space, the flow velocity of the gas flow and thus the undesirable acceleration of the bulk material flow within the second annular free space also increases.

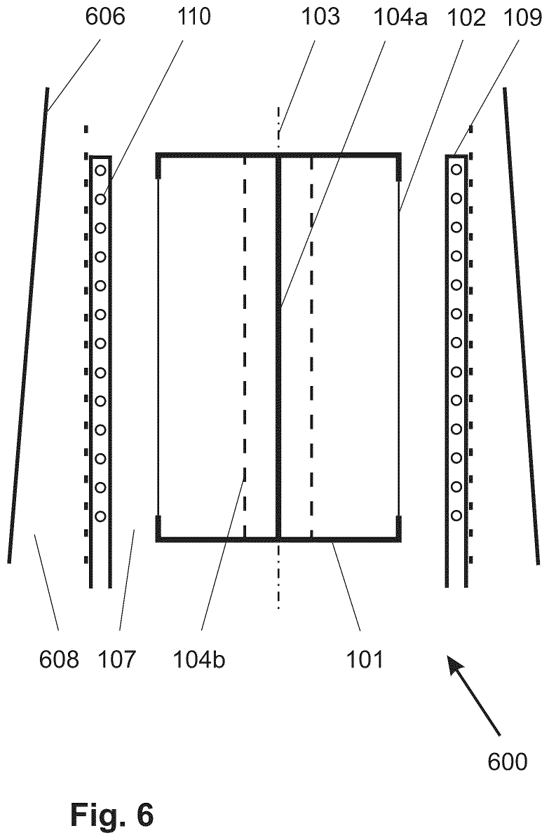

In FIG. 6, a third alternative apparatus 600 according to the invention is thus shown schematically in a vertical section. Apparatus 600 differs from the above-described apparatuses only in that the electron reflector 606 is not designed as a hollow cylinder, but instead has the shape of the exterior surface of a truncated cone, such that the second annular free space 608 has an annular shape, in which the outer diameter and thus the cross-sectional arca grows continuously towards the bottom. This design of the second annular free space 608 counteracts a downwardly increasing flow velocity of the protective and flushing mixture within the second annular free space 608 and thus prevents additional acceleration of the bulk material particles.

A downwardly increasing flow rate within the second annular free space in an apparatus according to the invention can also be counteracted if openings are introduced into the wall of the electron reflector 106 or 606 through which gas can escape horizontally from the second annular free space, thereby reducing the vertical flow rate within the second annular free space. The horizontal partial flow must be dimensioned such that the predominantly vertical fall direction of the bulk particles is affected little, but dust and grit are effectively carried away radially outwards.

Electron beam generators are known from the prior art and also generate a ring of accelerated electrons, however, their movements are directed radially inwards. This also allows an annular curtain of falling bulk particles to be exposed to the accelerated electrons. However, with the same diameters of this bulk material curtain, an electron beam generator according to the invention with radially outwardly directed electron propagation is significantly more compact than a similar prior-art electron beam generator. In the prior-art electron beam generator, all essential components (determining the function and cost of the electron beam generator) are arranged outside the ring of falling bulk particles so that they enclose the bulk material particle curtain. In an apparatus according to the invention, however, all essential components are arranged inside the annular bulk particle curtain. Therefore, in an apparatus according to the invention, many components can be dimensioned smaller than is the case in the prior art, which is more cost-effective. Furthermore, an apparatus according to the invention with radially diverging electron propagation can also be used inside hollow bodies, e.g., for treating the inner pipe wall. The axial orientation of the shielding gas pipes, sensor cables and cooling channels and their arrangement in the same shadowing angle regions further allows free axial scaling of the electron beam generator and thus of the dose rate of an apparatus according to the invention.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. An apparatus for exposing bulk material to accelerated electrons, the apparatus comprising:
a cylindrical housing which encloses an evacuable space;
a cylindrical electron exit window as a component of the cylindrical housing;
at least one wire-shaped, strand-shaped, rod-shaped, annular or cylindrical cathode, which is arranged within the evacuable space and enclosed by the cylindrical electron exit window, wherein a first power supply device is connected in an electrically conductive manner between the wire-shaped, strand-shaped, rod-shaped, annular or cylindrical cathode and the cylindrical electron exit window, such that electrons can be emitted from the wire-shaped, strand-shaped, rod-shaped, annular or cylindrical cathode and accelerated radially away from the cylinder axis of the cylindrical electron exit window towards the cylindrical electron exit window;
a cylindrical protective grid which encloses the cylindrical electron exit window and defines a first annular free space between the cylindrical electron exit window and the cylindrical protective grid;
an electron reflector which encloses the cylindrical protective grid and defines a second annular free space between the cylindrical protective grid and the electron reflector; and
a plurality of gas pipes which extend within the first annular free space parallel to the cylinder axis of the cylindrical electron exit window, wherein the gas pipes are spaced apart by an identical first dimension from the cylinder axis of the cylindrical electron exit window and by an identical second dimension from an adjacent gas pipe, and wherein each gas pipe has bores or at least one slot along the longitudinal extent of the gas pipe on opposing wall regions, through which a first gas can be introduced into the first annular free space.

2. The apparatus of claim 1, wherein the wire-shaped, strand-shaped, rod-shaped, annular or cylindrical cathode is a cold cathode.

3. The apparatus of claim 1, wherein the wire-shaped, strand-shaped, rod-shaped, annular or cylindrical cathode is a hot cathode.

4. The apparatus of claim 3, wherein the wire-shaped, strand-shaped, rod-shaped, annular or cylindrical cathode is a hot cathode heated directly by means of current flow.

5. The apparatus of claim 3, wherein the cathode is cylindrical and has a wire-, strand- or rod-shaped heating element extending along the cylinder axis, wherein the cylindrical cathode can be heated by means of thermal conduction, thermal radiation or electron impact.

6. The apparatus of claim 5, wherein one end of the cylindrical cathode is connected in an electrically conductive manner to one end of the wire-, strand- or rod-shaped heating element.

7. The apparatus of claim 1, comprising a cylindrical control grid which encloses the wire-shaped, strand-shaped, rod-shaped, annular or cylindrical cathode and which has a diameter which is smaller than the diameter of the cylindrical electron exit window.

8. The apparatus of claim 7, wherein the cylindrical control grid has a voltage difference with respect to the rod-shaped, annular or cylindrical cathode of approximately +20 V to approximately +2000 V, wherein a second power supply unit generates the electrical voltage potential for the cylindrical control grid.

9. The apparatus of claim 7, wherein the cylindrical control grid is not electron-transparent over its entire circumference, but only in defined opening regions, these opening regions being arranged centrally symmetrically to those of the cylindrical electron exit window.

10. The apparatus of claim 1, wherein the gas pipes are attached to the cylindrical protective grid.

11. The apparatus of claim 1, comprising at least one device for generating a flow of a second gas within the second annular free space.

12. The apparatus of claim 1, wherein the volume flow of the first gas into the first annular free space can be metered independently of the flow of a second gas within the second annular free space.

13. The apparatus of claim 1, wherein the electron reflector is electrically insulated from the electrical ground potential, and a third power supply device generates an electrical voltage potential at the electron reflector for igniting and maintaining a plasma within the second annular free space.

14. The apparatus of claim 1, wherein the cylinder axis of the cylindrical electron exit window is oriented vertically or at an angle of approximately 10° or less deviating from the vertical.

15. The apparatus of claim 1, comprising a device for separating and rotating a plurality of bulk material particles, comprising a cylindrical side wall and a disc-shaped or conical bottom wall, wherein an annular gap is formed between the cylindrical side wall and the disc-shaped or conical bottom wall.

16. The apparatus of claim 1, wherein the electron reflector is designed as a hollow cylinder or in that the electron reflector has the shape of the outer surface of a truncated cone.

17. The apparatus of claim 1, wherein the electron reflector has openings in the wall.

18. The apparatus of claim 1, wherein the wire-shaped, strand-shaped, rod-shaped, annular or cylindrical cathode is firmly clamped only at the upper end and is contacted at the lower end with an axially movable clamping piece.

19. The apparatus of claim 1, wherein the wire-shaped, strand-shaped, rod-shaped, annular or cylindrical cathode is firmly clamped or supported only at the lower end and contacted at the upper end with an axially movable clamping piece.

20. The apparatus of claim 1, wherein the radial position of the wire-shaped, strand-shaped, rod-shaped, annular or cylindrical cathode is adjustable.
